(19) United States
(12) Patent Application Publication
(10) Pub. No.: US 2014/0356997 A1
(43) Pub. Date: Dec. 4, 2014

(54) DONOR SUBSTRATE, METHOD OF MANUFACTURING THE SAME, AND METHOD OF FORMING TRANSFER PATTERN USING THE SAME

(71) Applicant: Samsung Display Co., Ltd., Yongin-city (KR)

(72) Inventor: YoungGil KWON, Suwon-si (KR)

(73) Assignee: Samsung Display Co., Ltd., Yongin-city (KR)

(21) Appl. No.: 14/022,754

(22) Filed: Sep. 10, 2013

(30) Foreign Application Priority Data
May 28, 2013 (KR) 10-2013-0060489

(51) Int. Cl. H01L 51/00; H01L 51/56

(52) U.S. Cl. CPC H01L 51/0021; H01L 51/0002; H01L 51/56
USPC 438/34; 438/99; 428/32.8

(57) ABSTRACT

A donor substrate includes a base layer, a light-to-heat conversion layer disposed on the base layer, a metal particle layer disposed on the base layer and which discharges static electricity, and a transfer layer disposed on the light-to-heat conversion layer.

This application claims priority to Korean Patent Application No. 10-2013-0060489, filed on May 28, 2013, and all the benefits accruing therefrom under 35 U.S.C. §119, the content of which in its entirety is herein incorporated by reference.

### BACKGROUND

1. Field of Disclosure

The disclosure relates to a donor substrate, a method of manufacturing the donor substrate, and a method of forming a transfer pattern using the donor substrate. More particularly, the disclosure relates to a donor substrate which discharges static electricity thereof, a method of manufacturing the donor substrate, and a method of forming a transfer pattern using the donor substrate.

2. Description of the Related Art

In general, a laser-induced thermal imaging method is widely used in formation of an organic/inorganic pattern (hereinafter, referred to as a transfer pattern) on a target transfer substrate. For instance, the laser induced thermal imaging method is used in fabrication of an organic light emitting device.

The laser induced thermal imaging method may utilize a donor substrate. The donor substrate typically includes a light-to-heat conversion layer to convert light provided from a light source to heat, and a transfer layer disposed on the light-to-heat conversion layer.

### SUMMARY

The disclosure provides exemplary embodiments of a donor substrate including a metal particle layer which discharge static electricity.

The disclosure provides a method of manufacturing the donor substrate.

The disclosure provides a method of forming a transfer pattern using the donor substrate.

In an exemplary embodiment of the invention, a donor substrate includes a base layer, a light-to-heat conversion layer disposed on the base layer, a metal particle layer disposed on the base layer and which discharges static electricity, and a transfer layer disposed on the light-to-heat conversion layer.

In an exemplary embodiment, the base layer may include a synthetic resin, and the metal particle layer may include silver particles.

In an exemplary embodiment, the metal particle layer may be disposed between the base layer and the light-to-heat conversion layer.

In an exemplary embodiment, the metal particle layer may be disposed between the light-to-heat conversion layer and the transfer layer.

In an exemplary embodiment, the donor substrate may further include an intermediate layer disposed between the light-to-heat conversion layer and the transfer layer, where the light-to-heat conversion layer includes a light absorbing material, and the intermediate layer effectively prevents the light absorbing material of the light-to-heat conversion layer from diffusing to the transfer layer.

In an exemplary embodiment, the intermediate layer may be disposed between the metal particle layer and the transfer layer.

In an exemplary embodiment, the donor substrate may further include a protective layer disposed on the transfer layer.

In another exemplary embodiment of the invention, a method of manufacturing a donor substrate includes providing a light-to-heat conversion layer on a base layer, providing a metal ink layer on the base layer, sintering the metal ink layer using light to form a metal particle layer, and providing a transfer layer on the light-to-heat conversion layer.

In an exemplary embodiment, the method may further include irradiating a microwave on the metal particle layer.

In an exemplary embodiment, the metal ink layer may be provided on the light-to-heat conversion layer on the base layer.

In an exemplary embodiment, the light-to-heat conversion layer may be provided on the metal particle layer.

In an exemplary embodiment, the method may further include providing a protective between the light-to-heat conversion layer and the transfer layer, where the light-to-heat conversion layer includes a light absorbing material, and the intermediate layer effectively prevents the light absorbing of the light-to-heat conversion layer from diffusing to the transfer layer.

In an exemplary embodiment, the intermediate layer may be provided on the metal particle layer.

In an exemplary embodiment, the method may further include providing a protective layer on the transfer layer.

In an exemplary embodiment, the metal ink layer may include silver particles.

In an alternative exemplary embodiment of the invention, a method of forming a transfer pattern includes disposing a donor substrate on a target transfer substrate, where the donor substrate includes a base layer, a light-to-heat conversion layer disposed on the base layer, a metal particle layer disposed on the base layer and which discharges static electricity, and a transfer layer disposed on the light-to-heat conversion layer, and where the transfer layer of the disposed donor substrate is in contact with the target transfer substrate, irradiating light on the donor substrate to allow a transfer pattern to be transferred to the target transfer substrate, and removing the donor substrate from the target transfer substrate.

In an exemplary embodiment, the method may further include removing a protective layer from the donor substrate before the disposing the donor substrate on the target transfer substrate, where the protective layer is disposed on the transfer layer of the donor substrate.

In an exemplary embodiment, the target transfer substrate may be a substrate of an organic light emitting display substrate.

In an exemplary embodiment, the organic light emitting display substrate may include an organic light emitting device, and the organic light emitting device may include the transfer pattern.

According to exemplary embodiment of the invention, as described herein, the metal particle layer discharges the static electricity generated during the manufacturing process of the donor substrate and the transferring process of the transfer pattern. Thus, the foreign substance may be effectively prevented from being attached to the transfer layer. In such embodiments, electrical parts integrated in the organic light emitting display substrate, on which the transfer pattern is disposed, may be protected from the static electricity.

In exemplary embodiments, as described herein, the metal particle layer may be formed by a photo-sintering process, which is performed faster than a heat sintering process. Therefore, a manufacturing time of the metal particle layer is shortened. In such embodiments, the sintering process is performed at a low temperature, and thus the base layer may be effectively prevented from being deformed. In such embodiments, the metal particle layer absorbs the microwave, such that the electrical conductivity of the metal particle layer is improved.

### BRIEF DESCRIPTION OF THE DRAWINGS

The above and other features of the invention will become more apparent by describing in further detail exemplary embodiments thereof with reference to the accompanying drawings, in which:

FIG. 1 is a plan view showing an exemplary embodiment of a donor substrate according to the invention;

FIG. 2A is a cross-sectional view taken along line I-I′ of the donor substrate shown in FIG. 1;

FIG. 2B is an scanning electron microscope (“SEM”) image showing an exemplary embodiment of a metal particle layer according to the invention;

FIG. 3 is a cross-sectional view showing an alternative exemplary embodiment of a donor substrate according to the invention;

FIG. 4 is a cross-sectional view showing another alternative exemplary embodiment of a donor substrate according to the invention;

FIGS. 5A to 5F are cross-sectional views showing an exemplary embodiment of a method of manufacturing a donor substrate according to the invention;

FIGS. 6A to 6D are cross-sectional views showing an exemplary embodiment of a method of forming a transfer pattern according to the invention; and

FIG. 7 is a cross-sectional view showing an exemplary embodiment of an organic light emitting display substrate including a transfer pattern according to the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings herein.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, exemplary embodiments of the invention will be described in further detail with reference to the accompanying drawings.

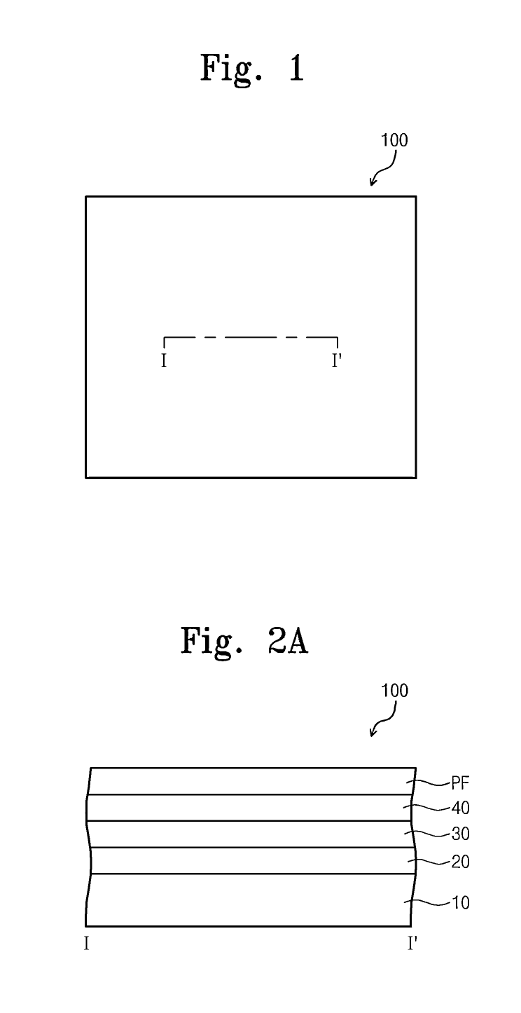

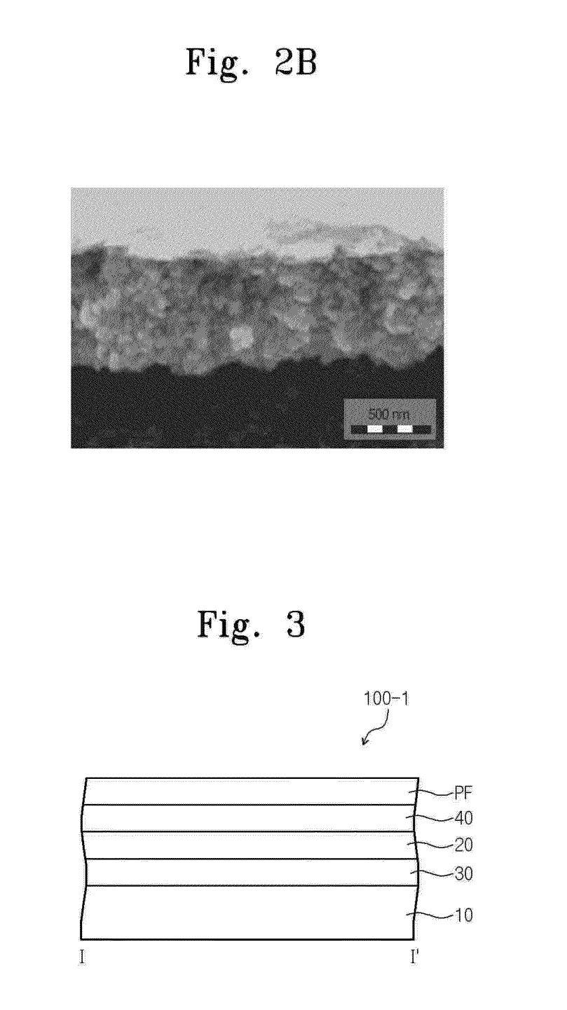

FIG. 1 is a plan view showing an exemplary embodiment of a donor substrate according to the invention, FIG. 2A is a cross-sectional view taken along line I-I′ of the donor substrate shown in FIG. 1, and FIG. 2B is a scanning electron microscope (“SEM”) image showing an exemplary embodiment of a metal particle layer according to the invention. Hereinafter, an exemplary embodiment of the donor substrate will be described with reference to FIGS. 1, 2A and 2B.

Referring to FIGS. 1 and 2A, an exemplary embodiment of the donor substrate 100 includes a base layer 10, a light-to-heat conversion layer 20, a metal particle layer 30 and a transfer layer 40. In such an embodiment, functional layers (not shown) may be disposed between the base layer 10 and the light-to-heat conversion layer 20.

The base layer 10 is transparent to transmit light incident thereto. The base layer 10 may include a synthetic resin. In one exemplary embodiment, for example, the base layer 10 includes at least one of polyester, polyacryl, polyepoxy, polyethylene, polyimide, polyacrylate, polystyrene or polyethyleneterephthalate. In an alternative exemplary embodiment, the base layer 10 may include glass or quartz. In an exemplary embodiment, the base layer 10 has a thickness in a range of about 10 micrometers (μm) to about 500 micrometers (μm).

The light-to-heat conversion layer 20 is disposed on the base layer 10. The light-to-heat conversion layer 20 absorbs incident light and converts the absorbed light to heat. The light-to-heat conversion layer 20 absorbs the light having a specific wavelength in the incident light, e.g., an ultraviolet ray wavelength region or a visible ray wavelength region.

The light-to-heat conversion layer 20 includes a material having a predetermined optical density and a light absorptivity. In one exemplary embodiment, for example, the light-to-heat conversion layer 20 may include a metal, such as aluminum (Al), nickel (Ni), molybdenum (Mo), titanium (Ti), zirconium (Zr), copper (Cu), vanadium (V), tantalum (Ta), palladium (Pd), ruthenium (Ru), iridium (Ir), gold (Au), silver (Ag), platinum (Pt), metallic oxides thereof, or metal sulfides thereof.

In an exemplary embodiment, the light-to-heat conversion layer 20 may include a light absorbing material and a polymer. The light absorbing material of the light-to-heat conversion layer 20 may be carbon black, graphite or infrared ray dye, for example. The light-to-heat conversion layer 20 may further include a binder. The light-to-heat conversion layer 20 has a single or multi-layer structure including the above-mentioned materials.

The metal particle layer 30 is disposed on the base layer 10. In such an embodiment, as shown in FIG. 2A, the metal particle layer 30 is disposed on the light-to-heat conversion layer 20.

Referring to FIG. 2B, the metal particle layer 30 includes photo sintered metal particles. In one exemplary embodiment, for example, the metal particles may be silver particles, but not being limited thereto. The metal particle layer 30 is provided, e.g., formed, by coalescing metal nanoparticles using a photo sintering process.

The metal particle layer 30 has substantially high conductivity to discharge static electricity. The silver particle layer may have an electrical conductivity of about 28 percent of a bulk silver, for example. The electrical conductivity of the metal particle layer 30 may be controlled based on conditions of the photo sintering process. In such embodiment, the electrical conductivity of the metal particle layer 30 may be improved by irradiating a microwave on the metal particle layer 30. The metal particle layer 30 discharges the static electricity generated when the donor substrate 100 is manufactured and a transfer pattern is formed using the donor substrate 100.

As shown in FIG. 2A, the transfer layer 40 is disposed on the light-to-heat conversion layer 20. In such an embodiment, the transfer layer 40 is disposed on the metal particle layer 30. The transfer layer 40 includes organic and inorganic materials transferred by heat energy applied thereto. In one exemplary embodiment, for example, the transfer layer 40 includes an organic material of a color filter or a functional material included in the organic light emitting device, but not being limited to a specific material.

A protective layer PF is disposed on the transfer layer 40. The protective layer PF effectively prevents the transfer layer 40 from being damaged while the donor substrate 100 moves. The protective layer PF may include a plastic film, which is attachable to and detachable from the transfer layer 40. The static electricity, which may be generated when the protective layer PF is attached to the transfer layer 40, is discharged through the metal particle layer 30.

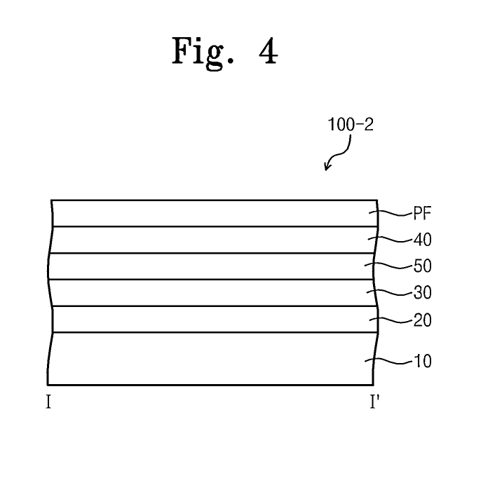

FIG. 3 is a cross-sectional view showing an alternative exemplary embodiment of a donor substrate according to the invention and FIG. 4 is a cross-sectional view showing another alternative exemplary embodiment of a donor substrate according to the invention. The same or like elements shown in FIGS. 3 and 4 have been labeled with the same reference characters as used above to describe the exemplary embodiments of donor substrate shown in FIG. 2, and any repetitive detailed description thereof may be omitted or simplified.

Referring to FIG. 3, an exemplary embodiment of a donor substrate 100-1 includes a base layer 10, a light-to-heat conversion layer 20, a metal particle layer 30 and a transfer layer 40. The donor substrate 100-1 has a different layer structure from the layer structure of the donor substrate 100 shown in FIG. 2.

In such an embodiment, as shown in FIG. 3, the metal particle layer 30 is directly disposed on a surface of the base layer 10. The light-to-heat conversion layer 20 is disposed on the metal particle layer 30. In such an embodiment, another functional layer (not shown) may be disposed between the base layer 10 and the metal particle layer 30.

Referring to FIG. 4, an alternative exemplary embodiment of a donor substrate 100-2 may further include an intermediate layer 50. The intermediate layer 50 is disposed between the light-to-heat conversion layer 20 and the transfer layer 40. In such an embodiment, the intermediate layer 50 effectively prevents the transfer layer 40 from being contaminated by the light absorbing material, e.g., carbon black, included in the light-to heat conversion layer 20. The intermediate layer 50 includes polymer, metal, inorganic material, inorganic oxide material or organic/inorganic complex material, for example.

The intermediate layer 50 is disposed on the metal particle layer 30. In another alternative exemplary embodiment, the metal particle layer 30 may be disposed directly on the surface of the base layer 10, and the intermediate layer 50 may be disposed directly on a surface of the light-to-heat conversion layer 20.

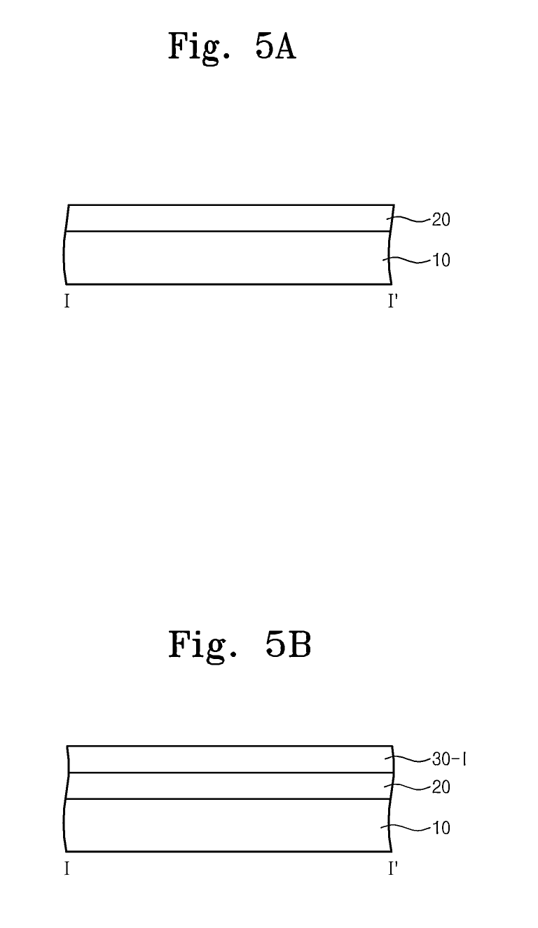

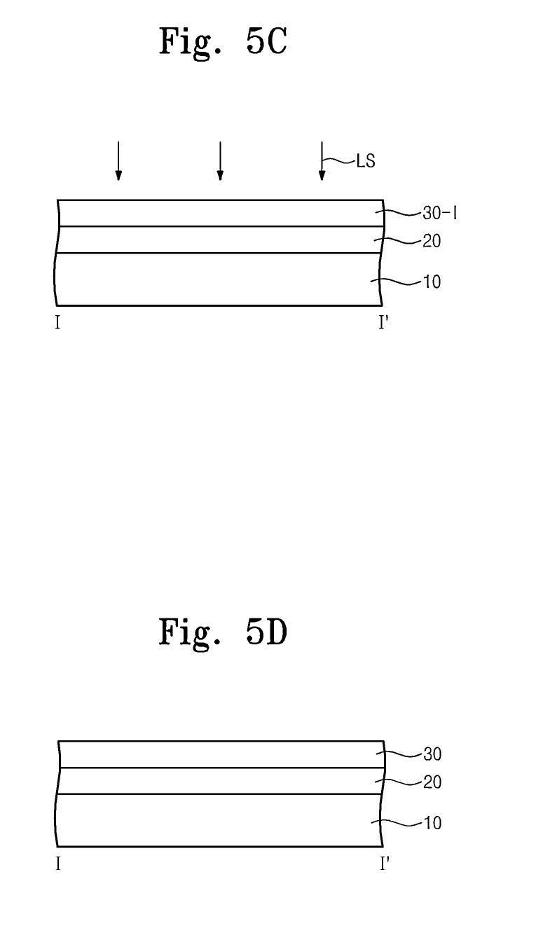

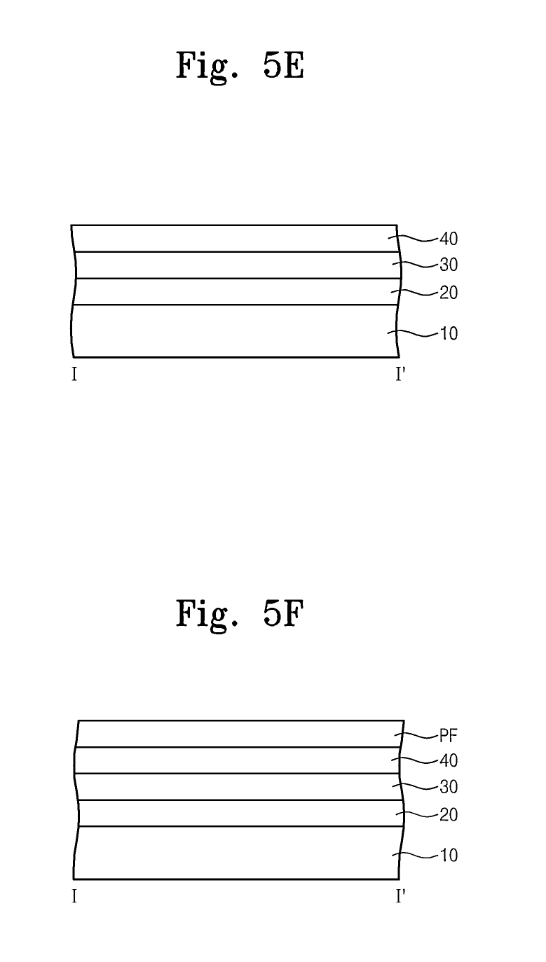

FIGS. 5A to 5F are cross-sectional views showing an exemplary embodiment of a method of manufacturing a donor substrate according to the invention. FIGS. 5A to 5F show an exemplary embodiment of the method of manufacturing the donor substrate 100 shown in FIG. 2A.

Referring to FIG. 5A, the light-to-heat conversion layer 20 is provided, e.g., formed, on the base layer 10. The method of providing the light-to-heat conversion layer 20 is determined based on the material thereof. In one exemplary embodiment, for example, the light-to-heat conversion layer 20, which includes metal oxide, metal sulfide, carbon black, graphite, for example, may be provided, e.g., formed, by a vacuum deposition process, an electron-beam deposition process, or a sputtering process. In one exemplary embodiment, for example, the light-to-heat conversion layer 20, which includes polymer, may be provided, e.g., formed, by a roll coating method, an extrusion coating method, a spin coating method, a knife coating method, or an inkjet coating method.

Referring to FIG. 5B, a metal ink layer 30-I is provided, e.g., formed, on the light-to-heat conversion layer 20. In one exemplary embodiment, for example, the metal ink layer 30-I may be formed by coating metal ink on the light-to-heat conversion layer 20. In an alternative exemplary embodiment, the metal ink layer 30-I may be formed by the roll coating method, the extrusion coating method, the spin coating method, the knife coating method, or the inkjet coating method.

In such an embodiment, the metal ink includes an organic solvent and metal nanoparticles distributed in the organic solvent. In one exemplary embodiment, for example, the metal ink includes an ethanol-ethylene glycol mixed solvent and silver nanoparticles distributed in the ethanol-ethylene glycol mixed solvent. The metal ink may include silver nanoparticles of about 20 weight percent (wt %). Each silver nanoparticle has a diameter in a range of about 30 nanometers (nm) to about 50 nanometers (nm).

Then, as shown in FIGS. 5C and 5D, the metal ink layer 30-I is photo sintered to provide the metal particle layer 30. In such an embodiment, the light LS may be intermittently irradiated several times on the metal ink layer 30-I using a high intensity flash lamp. In such an embodiment, the light LS is irradiated during a few microseconds to a few milliseconds at each irradiation stage.

In an exemplary embodiment, an intense pulsed light (“IPL”) in the visible ray wavelength region may be irradiated on the metal ink layer 30-I. In such an embodiment, the light may be irradiated thirty-two times on the metal ink layer 30-I using the flash lamp with a maximum power of about 1000 watts (W) and a wavelength region of about 350 nm to about 900 nm. In such an embodiment, the light may be irradiated during about 10 milliseconds (ms) at each irradiation stage.

Accordingly, the organic solvent is evaporated and a metal precursor, e.g., silver precursor, is thermally converted. The metal precursor having a melting point lower than a melting point of the bulk silver is rapidly sintered by the IPL. The photo sintering method may be applied to a roll-to-roll manufacturing process.

Then, referring to FIG. 5E, the transfer layer 40 is provided, e.g., formed, on the metal particle layer 30. The transfer layer 40 may be formed by the vacuum deposition process, the sputtering process, or the coating process based on the material thereof.

Referring to FIG. 5F, the protective layer PF is provide, e.g., formed, on the transfer layer 40. The protective layer PF may be attached onto the transfer layer 40 through a lamination process. In such an embodiment, the static electricity generated during the lamination process is discharged through the metal particle layer 30. The protective layer PF may be omitted in an alternative exemplary embodiment of the donor substrate 100.

Although not shown in figures, an exemplary embodiment of the manufacturing method of the donor substrate 100 may further include irradiating the microwave onto the metal particle layer 30 before providing the transfer layer 40. In such an embodiment, the microwave with a power of several watts may be irradiated on the metal particle layer 30 during several seconds.

In such an embodiment, after the metal ink layer 30-I is sintered to form the metal particle layer 30, the light incident to the metal particle layer 30 is reflected. Accordingly, the electrical conductivity of the metal particle layer 30 is not increased regardless of the sintering time after a predetermined amount of the metal ink layer 30-I is sintered. In such an embodiment, the microwave is absorbed by the metal particle layer 30 to increase a conductance of the metal particle layer 30. Therefore, the electrical conductivity of the metal particle layer 30 increases, and a static electricity discharge rate of the donor substrate 100 is thereby substantially improved.

The donor substrate 100-1 shown in FIG. 3 is manufactured by adjusting the manufacturing order of the exemplary embodiment of manufacturing the donor substrate shown in FIGS. 5A to 5F. In such an embodiment, the metal ink layer 30-I may be provided, e.g., formed, on the base layer 10 and photo sintered to form the metal particle layer 30. The light-to-heat conversion layer 20 is provided on the metal particle layer 30. The process thereafter is substantially the same as a corresponding process of the exemplary embodiment shown in FIGS. 5A to 5F.

The exemplary embodiment of the donor substrate 100-2 shown in FIG. 4 may be manufactured by further providing the intermediate layer 50 during the exemplary embodiment of the method of manufacturing the donor substrate shown in FIGS. 5A to 5F. In such an embodiment, the intermediate layer 50 may be formed on the metal particle layer 30 using a vacuum deposition process, a thermal deposition process, a slit coating process, or a spin coating process, for example.

The process thereafter is substantially the same as a corresponding process of the exemplary embodiment shown in FIGS. 5A to 5F. In an exemplary embodiment, where the metal particle layer 30 is provided prior to the light-to-heat conversion layer 20, the intermediate layer 50 may be provided, e.g., formed, on the light-to-heat conversion layer 20.

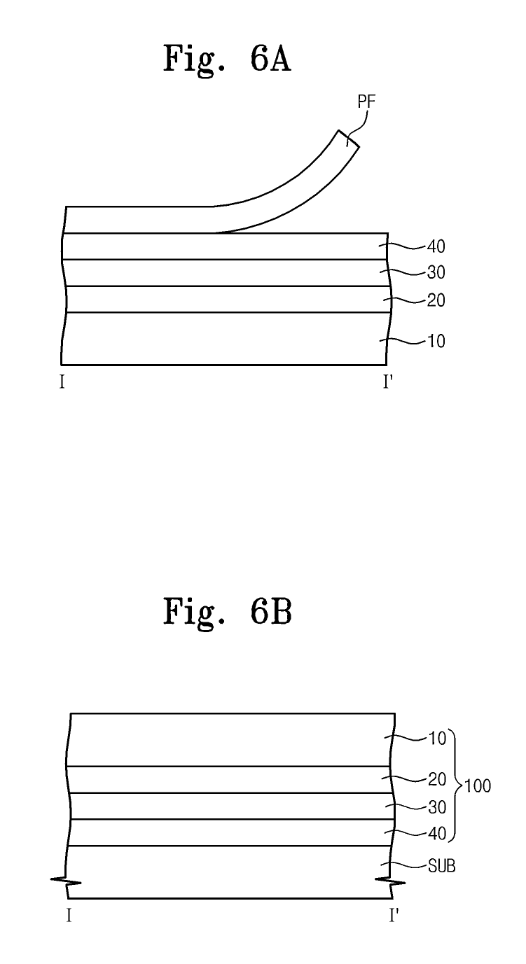

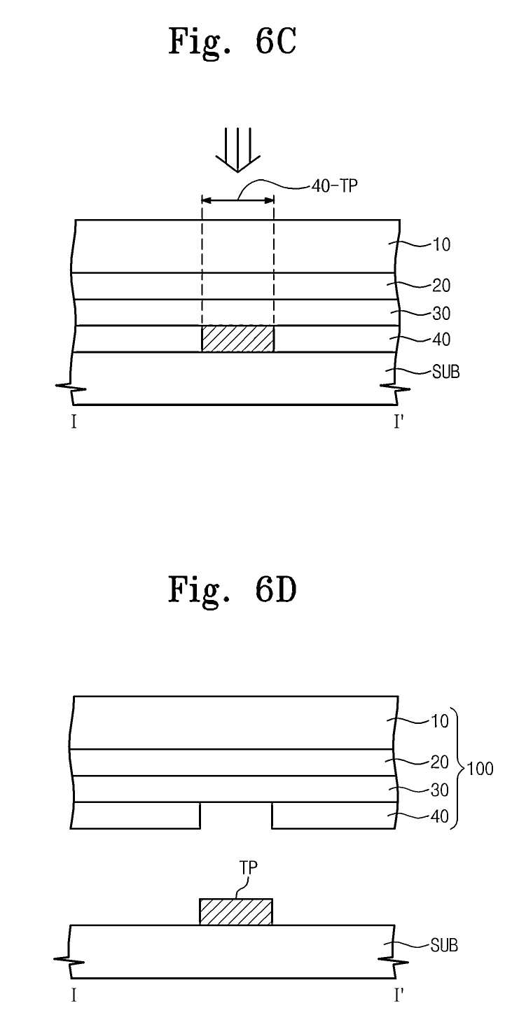

FIGS. 6A to 6D are cross-sectional views showing an exemplary embodiment of a method of forming a transfer pattern according to the invention. FIGS. 6A to 6D show a method of forming a transfer pattern in the exemplary embodiment of the donor substrate 100 shown in FIG. 2A, but the exemplary embodiments of the donor substrates 100-1 and 100-2 shown in FIGS. 3 and 4 may be manufactured through the method.

Referring to FIG. 6A, the protective layer PF disposed on the transfer layer 40 is removed from the transfer layer 40. The static electricity generated when the protective layer PF is removed is discharged through the metal particle layer 30. Thus, a foreign substance may be effectively prevented from being attached to the transfer layer 40. In an exemplary embodiment, where the donor substrate 100 does not include the protective layer PF, the removal process of the protective layer PF may be omitted.

Referring to FIG. 6B, the donor substrate 100 is disposed on a target transfer substrate SUB such that the transfer layer 40 is in contact with the target transfer substrate SUB. The target transfer substrate SUB may further include an insulating layer (not shown). The insulating layer may include an organic layer and/or an inorganic layer. The target transfer substrate SUB may function as a portion of an organic light emitting display substrate.

The static electricity generated when the transfer layer 40 is disposed to contact the target transfer substrate SUB is discharged through the metal particle layer 30. Therefore, electrical parts integrated in the organic light emitting display substrate may be protected from the static electricity.

Referring to FIG. 6C, the light, e.g., an ultraviolet ray or a visible ray, is irradiated on the donor substrate 100. In such an embodiment, the light may be a laser beam with a constant wavelength.

In such an embodiment, the light may be irradiated onto a portion 40-TP of the donor substrate 100 to transfer the portion 40-TP of the transfer layer 40 onto the target transfer substrate SUB. In such an embodiment, a light source that regionally provides the light may be used to irradiate the light.

In an alternative exemplary embodiment, a light source that provides the light to the entire surface of the donor substrate 100 and a mask that partially transmits the light from the light source may be used to irradiate the light onto the portion 40-TP of the donor substrate 100. In an alternative exemplary embodiment, the light may be irradiated on substantially an entire surface of the donor substrate 100 to transfer substantially an entire portion of the transfer layer 40.

Referring to FIG. 6D, a transfer pattern TP corresponding to the portion 40-TP of the donor substrate 100, onto which the light is irradiated, is provided on the target transfer substrate SUB. In such an embodiment, when the transfer pattern TP is provided on the target transfer substrate SUB, the donor substrate 100 is removed from the target transfer substrate SUB.

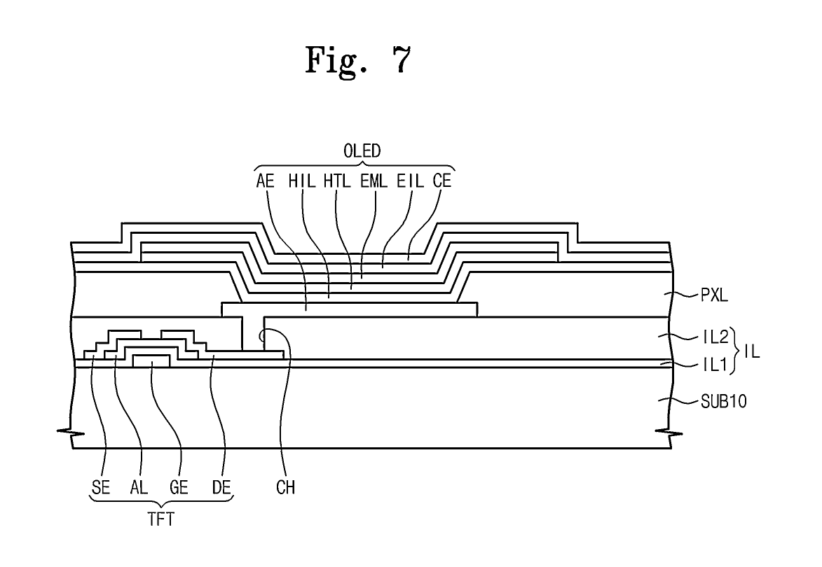

FIG. 7 is a cross-sectional view showing an exemplary embodiment of the organic light emitting display substrate including a transfer pattern according to the invention. The organic light emitting display substrate includes a base substrate SUB10, a thin film transistor TFT disposed on the base substrate SUB10, insulating layers IL, and an organic light emitting device OLED. The thin film transistor TFT and the organic light emitting device OLED are disposed in each pixel area defined on the organic light emitting display substrate. In an exemplary embodiment, the pixels PXL are arranged on the base substrate SUB10 substantially in a matrix form. In such an embodiment, the organic light emitting display substrate further includes a plurality of lines (now shown) that applies electrical signals to the pixels.

Referring to FIG. 7, a gate electrode GE of the thin film transistor TFT is disposed on the base substrate SUB10. The base substrate SUB10 corresponds to the target transfer substrate SUB described with reference to FIGS. 6A to 6D.

A first insulating layer IL1 of the insulating layers IL is disposed on the base substrate SUB10 to cover the gate electrode GE. A semiconductor layer AL is disposed on the first insulating layer IL1. An input electrode SE and an output electrode DE are disposed on the first insulating layer IL1 to overlap the semiconductor layer AL.

A second insulating layer IL2 of the insulating layers IL is disposed on the first insulating layer IL1 to cover the input electrode SE and the output electrode DE. The organic light emitting device OLED is disposed on the second insulating layer IL2. The organic light emitting device OLED includes a first electrode AE, a hole injection layer HIL, a hole transport layer HTL, an organic light emitting layer EML, an electron injection layer EIL and a second electrode CE, which are sequentially stacked on the second insulating layer IL2. The first electrode AE is connected to the output electrode DE through a contact hole CH defined through the second insulating layer IL2.

The structure of the organic light emitting device OLED should not be limited to the structure of the exemplary embodiment of the organic light emitting device OLED shown in FIG. 7. In an alternative exemplary embodiment, the electron injection layer EIL may be omitted, and the organic light emitting device OLED may further include an electron transport layer disposed between the organic light emitting layer EML and the electron injection layer EIL.

In an exemplary embodiment, as shown in FIG. 7, the hole injection layer HIL and the electron injection layer EIL are commonly disposed between adjacent pixels PXL. In an alternative exemplary embodiment, the hole transport layer HTL and the organic light emitting layer EML may be disposed in each pixel PXL.

In such an embodiment, the hole transport layer HTL and the organic light emitting layer EML may be provided through an exemplary embodiment of the method described with reference to FIGS. 6A to 6D. In such an embodiment, the hole injection layer HIL and the electron injection layer EIL may be provided by irradiating the light on substantially the entire portion of the donor substrate 100 as described with reference to FIG. 6C.

Although the exemplary embodiments of the invention have been described, it is understood that the invention should not be limited to these exemplary embodiments but various changes and modifications can be made by one ordinary skilled in the art within the spirit and scope of the invention as hereinafter claimed.

What is claimed is:

1. A donor substrate comprising:
a base layer;
a light-to-heat conversion layer disposed on the base layer;
a metal particle layer disposed on the base layer and which discharges static electricity; and
a transfer layer disposed on the light-to-heat conversion layer.

2. The donor substrate of claim 1, wherein the base layer comprises a synthetic resin.

3. The donor substrate of claim 1, wherein the metal particle layer comprises silver particles.

4. The donor substrate of claim 3, wherein the metal particle layer is disposed between the base layer and the light-to-heat conversion layer.

5. The donor substrate of claim 3, wherein the metal particle layer is disposed between the light-to-heat conversion layer and the transfer layer.

6. The donor substrate of claim 3, further comprising:
a protective layer disposed on the transfer layer.

7. The donor substrate of claim 1, further comprising:
an intermediate layer disposed between the light-to-heat conversion layer and the transfer layer,
wherein the light-to-heat conversion layer comprises a light absorbing material, and
wherein the intermediate layer effectively prevents the light absorbing material of the light-to-heat conversion layer from diffusing to the transfer layer.

8. The donor substrate of claim 7, wherein the intermediate layer is disposed between the metal particle layer and the transfer layer.

9. A method of manufacturing a donor substrate, the method comprising:
providing a light-to-heat conversion layer on a base layer;
providing a metal ink layer on the base layer;
sintering the metal ink layer using light to form a metal particle layer; and
providing a transfer layer on the light-to-heat conversion layer.

10. The method of claim 9, further comprising:
irradiating a microwave on the metal particle layer.

11. The method of claim 9, wherein the metal ink layer is provided on the light-to-heat conversion layer on the base layer.

12. The method of claim 9, wherein the light-to-heat conversion layer is provided on the metal particle layer.

13. The method of claim 9, further comprising:
providing an intermediate layer between the light-to-heat conversion layer and the transfer layer,
wherein the light-to-heat conversion layer comprises a light absorbing material, and
wherein the intermediate layer effectively prevents the light absorbing material of the light-to-heat conversion layer from diffusing to the transfer layer.

14. The method of claim 13, wherein the intermediate layer is provided on the metal particle layer.

15. The method of claim 9, further comprising:
providing a protective layer on the transfer layer.

16. The method of claim 9, wherein the metal ink layer comprises silver particles.

17. A method of forming a transfer pattern, the method comprising:
disposing a donor substrate on a target transfer substrate, wherein the disposed donor substrate comprises a base layer, a light-to-heat conversion layer disposed on the base layer, a metal particle layer disposed on the base layer and which discharges static electricity, and a transfer layer disposed on the light-to-heat conversion layer, and wherein the transfer layer of the disposed donor substrate is in contact with the target transfer substrate;
irradiating light on the donor substrate to allow a transfer pattern to be transferred to the target transfer substrate; and
removing the donor substrate from the target transfer substrate.

18. The method of claim 17, further comprising:
removing a protective layer from the donor substrate before the disposing the donor substrate on the target transfer substrate,
wherein the protective layer is disposed on the transfer layer of the donor substrate.

19. The method of claim 17, wherein the target transfer substrate is a substrate of an organic light emitting display substrate.

20. The method of claim 19, wherein
the organic light emitting display substrate comprises an organic light emitting device, and
the organic light emitting device comprises the transfer pattern.
